(19) United States
(12) Patent Application Publication
(10) Pub. No.: US 2011/0284938 A1
(43) Pub. Date: Nov. 24, 2011

(54) SPIN TRANSISTOR AND INTEGRATED CIRCUIT

(75) Inventors: Shigeru Kawanaka, Yokohama-Shi (JP); Kanna Adachi, Chigasaki-Shi (JP); Yoshiyuki Kondo, Yokohama-Shi (JP)

(73) Assignee: KABUSHIKI KAISHA TOSHIBA, Tokyo (JP)

(21) Appl. No.: 13/053,399

(22) Filed: Mar. 22, 2011

(30) Foreign Application Priority Data
May 18, 2010 (JP) 2010-113873

(51) Int. Cl. H01L 29/82

(52) U.S. Cl. 257/295; 257/E29.323

(57) ABSTRACT

A spin transistor according to an embodiment includes: a first magnetic region supplying a first polarized signal polarized in a first magnetization direction in accordance with a first input signal; a second magnetic region supplying a second polarized signal polarized in a second magnetization direction opposite from the first magnetization direction in accordance with a second input signal, the second input signal being different from the first input signal; and a third magnetic region outputting the first polarized signal supplied from the first magnetic region in accordance with a third input signal, and outputting the second polarized signal supplied from the second magnetic region in accordance with a fourth input signal different from the third input signal.

### CROSS-REFERENCE TO RELATED APPLICATION

This application is based upon and claims the benefit of priority from prior Japanese Patent Application No. 2010-113873 filed on May 18, 2010 in Japan, the entire contents of which are incorporated herein by reference.

### FIELD

Embodiments described herein relate generally to a spin transistor and an integrated circuit.

### BACKGROUND

Recently, spin FETs that use a magnetic material for the sources and drains of conventional MOSFETs (Metal-Oxide-Semiconductor Field-Effect Transistors), and generate ON and OFF states by utilizing changes in magnetization direction of the magnetic material in accordance with the applied voltage have been known.

Such a spin FET has a two-dimensional electronic channel as the channel, and carriers move in the two-dimensional electronic channel. The precession of the carriers moving in the two-dimensional electronic channel is controlled by the Rashba effect. Where the spins of the carriers at the drain end are parallel to the spins in the drain, the carriers are conducted through the drain region. Where the spins of the carriers at the drain end are antiparallel to the spins in the drain, the carriers are not conducted through the drain. In this spin FET, however, high-precision carrier spin control needs to be performed in the channel. If there are fluctuations in the characteristics and processes, the standby power consumption becomes particularly high.

### BRIEF DESCRIPTION OF THE DRAWINGS

FIG. 1(a) is a top view of a spin transistor according to a first embodiment;

FIG. 1(b) is a cross-sectional view of the spin transistor according to the first embodiment, taken along the line I(a)-I(a) of FIG. 1(a);

FIG. 2(a) is a schematic view showing the relationship between the spin state density and the Fermi energy of a half-metal ferromagnetic material according to the first embodiment;

FIG. 2(b) is a circuit diagram of the spin transistor according to the first embodiment;

FIGS. 3(a) through 3(f) are cross-sectional views of relevant parts, showing a method of manufacturing the spin transistor according to the first embodiment;

FIG. 4(a) is a circuit diagram showing a case where a V_{CC} signal is input to a third magnetic region according to the first embodiment;

FIG. 4(b) is a circuit diagram showing a case where a GND signal is input to the third magnetic region according to the first embodiment;

FIG. 5 is a circuit diagram of spin transistors that are cascade-connected according to a second embodiment;

FIG. 6(a) is a circuit diagram of a NAND operational circuit using a spin transistor according to a third embodiment;

FIG. 6(b) is a truth table of the NAND operational circuit according to the third embodiment;

FIG. 6(c) is a circuit diagram of the NAND operational circuit using the spin transistor according to the third embodiment; and

FIGS. 7(a) and 7(b) are circuit diagrams of the NAND operational circuit using the spin transistor according to the third embodiment.

### DETAILED DESCRIPTION

A spin transistor according to an embodiment includes: A spin transistor comprising: a first magnetic region including a first input terminal; a second magnetic region including a second input terminal; a third magnetic region including a first output terminal; and a third input terminal. The first magnetic region supplies a first polarized signal polarized in a first magnetization direction in accordance with a first input signal input through the first input terminal. The second magnetic region supplies a second polarized signal polarized in a second magnetization direction opposite from the first magnetization direction in accordance with a second input signal input through the second input terminal, the second input signal being different from the first input signal. The third magnetic region outputs the first polarized signal supplied from the first magnetic region in accordance with a third input signal input through the third input terminal, and outputs the second polarized signal supplied from the second magnetic region in accordance with a fourth input signal input through the third input terminal, the fourth input signal being different from the third input signal.

### First Embodiment

### (Structure of a Semiconductor Device)

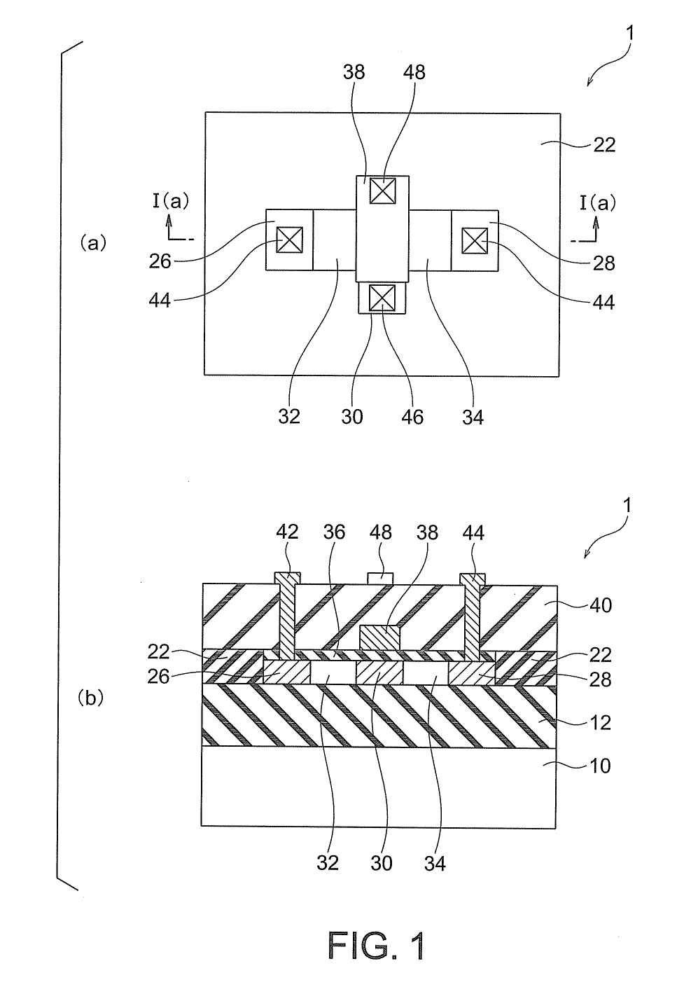

FIG. 1(a) is a top view of a spin transistor according to a first embodiment. FIG. 1(b) is a cross-sectional view of the spin transistor, taken along the line I(a)-I(a) of FIG. 1(a).

This spin transistor 1 includes a first magnetic region 26 that has a contact 42 as a first input terminal and supplies a signal polarized in a first magnetization direction in accordance with a first signal that is input through the contact 42. The spin transistor 1 also includes a second magnetic region 28 that has a contact 44 as a second input terminal and supplies a signal polarized in a second magnetization direction in accordance with a second signal that is input through the contact 44. The second magnetization direction is the opposite direction from the first magnetization direction. The spin transistor 1 also includes a third magnetic region 30 that has a contact 46 as a first output terminal. The spin transistor 1 also includes a contact 48 as a third input terminal. The contact 48 is electrically connected to a gate electrode 38, and the third magnetic region 30 is capacitive-coupled with the gate electrode 38 through a gate insulating film 36. The third magnetic region 30 outputs, through the contact 46, the signal polarized in the first magnetization direction and supplied from the first magnetic region 26, in accordance with a third signal that is input through the contact 48. The third magnetic region 30 also outputs, through the contact 46, the signal polarized in the second magnetization direction and supplied from the second magnetic region 28, in accordance with a fourth signal that is input through the contact 48.

In this spin transistor 1, the first magnetic region 26, a first conductive region 32, the third magnetic region 30, a second conductive region 34, and the second magnetic region 28 are arranged adjacent to one another on a first insulating film 12, as shown in FIGS. 1(a) and 1(b). In the spin transistor 1, however, the first magnetic region 26, the first conductive region 32, the third magnetic region 30, the second conductive region 34, and the second magnetic region 28 may not be adjacent to one another.

A device isolating region 22 having a STI (Shallow Trench Isolation) structure is formed around the first through third magnetic regions 26, 28, and 30, and the first and second conductive regions 32 and 34. The device isolating region 22 is made of SiO₂, for example.

The first insulating film 12 is formed on a semiconductor substrate 10, for example. The first insulating film 12 is made of SiO₂, for example.

The semiconductor substrate 10 is a Si-based substrate containing Si as the main component, for example. The spin transistor 1 of this embodiment is manufactured with the use of a SOI substrate having a SOI (Silicon On Insulator) structure having the later described single-crystal layer formed on the semiconductor substrate 10 via the first insulating film 12.

An interlayer insulating film 40 is formed to cover the device isolating region 22, a gate insulating film 36, and a gate electrode 38, for example, as shown in FIG. 1(b). The interlayer insulating film 40 is made of SiN or SiO₂, for example.

The first magnetic region 26 is electrically connected to the contact 42 formed on the interlayer insulating film 40, for example. The second magnetic region 28 is electrically connected to the contact 44 formed on the interlayer insulating film 40, for example. The third magnetic region 30 is electrically connected to the contact 46 formed on the interlayer insulating film 40, for example. The gate electrode 38 is electrically connected to the contact 48 formed on the interlayer insulating film 40, for example.

The contacts 42, 44, 46, and 48 are made of a metal material such as Cu, Ta, W, or Ti. A diffusion preventing film to prevent diffusion of the metal material is formed around the contacts 42, 44, 46, and 48, for example, but such a diffusion preventing film is not shown in the drawings.

### (First Through Third Magnetic Regions)

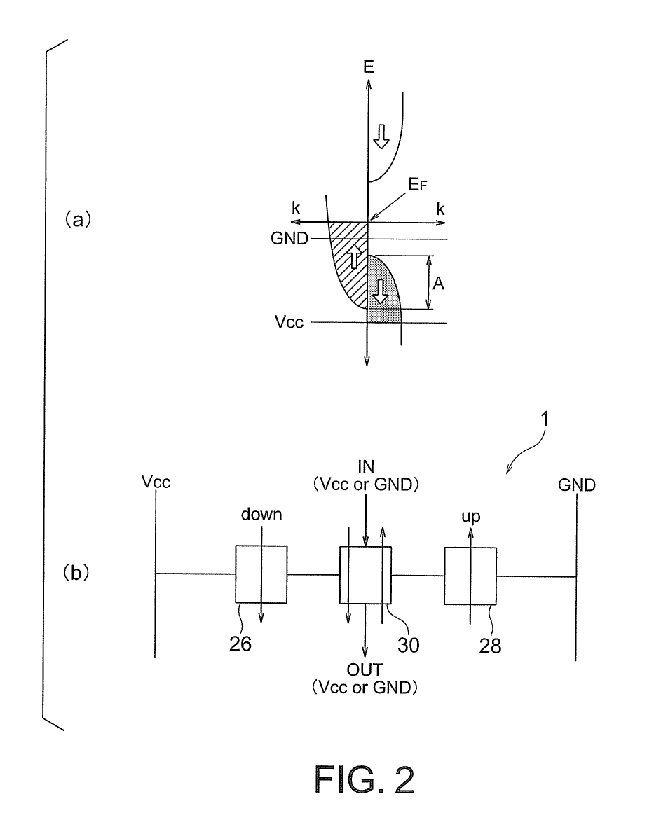

FIG. 2(a) is a schematic view showing the relationship between the spin state density and the Fermi energy of a half-metal ferromagnetic body according to the first embodiment. FIG. 2(b) is a circuit diagram of the spin transistor according to the first embodiment. In FIG. 2(a), the abscissa axis indicates the wave number k, the ordinate axis indicates the energy E of the electrons in crystals, V_{CC} represents the source voltage to be supplied from the power supply unit to the circuit, GND represents the ground potential, and E_{F} represents the Fermi level. The upward arrow shown in FIG. 2(a) schematically indicates that the spin state of the electrons in the crystals is upward (an “up state”), and the downward arrows schematically indicate that the spin state of the electrons in the crystals are a “down state”. The arrow shown below the characters “down” in FIG. 2(b) schematically indicates that the spin state of the electrons in the magnetic material is downward, and the arrow shown below the characters “up” schematically indicates that the spin state of the electrons in the magnetic material is upward. At the same time, the arrow shown below the characters “down” schematically indicates the magnetization direction of the magnetic material, and the arrow shown below the characters “up” schematically indicates the magnetization direction opposite from the magnetization direction of the “down state”.

Here, a V_{CC} signal as the source voltage is input to the first magnetic region 26 via the contact 42, as shown in FIG. 2(b). A GND signal as the ground potential is input to the second magnetic region 28 via the contact 44, as shown in FIG. 2(b). In this embodiment, the above mentioned first and third signals are V_{CC} signals, and the second and fourth signals are GND signals. The above mentioned third signal may not be equal the first signal, as long as the third signal directs the magnetization of the third magnetic region 30 downward, as shown in FIG. 2(a). In addition, the fourth signal may not be equal to the second signal, as long as the fourth signal directs the magnetization of the third magnetic region 30 upward, as shown in FIG. 2(a).

Each input signal from the previous stage is input to the gate electrode 38 via the contact 48, as shown in FIG. 2(b). Each output signal to the later stage is output from the third magnetic region 30 via the contact 46, as shown in FIG. 2(b).

The third magnetic region 30 accepts electrons spin-polarized by switching magnetization directions in accordance with signals that are input via the contact 48, the gate electrode 38, and the gate insulating film 36. Therefore, the spin transistor 1 outputs the spin-polarized electrons supplied from the first or second magnetic region 26 or 28, without an inversion layer formed immediately below the gate electrode 38. Outputting two types of signals in accordance with the magnetization direction of the third magnetic region 30, the spin transistor 1 as a single spin transistor realizes a switching circuit that has conventionally been realized by a CMOS (Complementary Metal Oxide Semiconductor), for example. Furthermore, the spin transistor 1 has a fewer contacts than in those in a conventional CMOS. It should be noted that, in the following description, the circuit connected to the IN side of the subject circuit will be referred to as the previous stage, and the circuit connected to the OUT side will be referred to as the later stage.

The first through third magnetic regions 26, 28, and 30 are preferably made of a ferromagnetic material that has a high consistency with III-V group semiconductors, a Curie temperature equal to or higher than room temperature (300 K, for example), and a wide bandgap in the vicinity of the Fermi level E_{F}. Such a ferromagnetic material is preferably a half-metal ferromagnetic material having a band structure in which the Fermi level E_{F} runs across one of the spin bands, and runs across a bandgap in the other spin band, for example, as shown in FIG. 2(a). This half-metal ferromagnetic material may be CrO₂, Fe₂O₃, Ga₁₋ₓMnₓAs, In₁₋ₓMnₓAs, Ge₁₋ₓMnₓ, or a Heusler alloy, for example. The Heusler alloy may be Co₂MnAl, Co₂NnGe, Co₂MnSi, Co₂CrAl, or Co₂FeAl, for example.

When a V_{CC} signal is input to the first magnetic region 26, the spin state of the electrons in the crystals is a down state, as shown in FIG. 2(a).

When a GND signal is input to the second magnetic region 28, the spin state of the electrons in the crystals is an up state, as shown in FIG. 2(a). The first and second magnetic regions 26 and 28 of this embodiment have spin states opposite to each other. In the spin transistor 1, when a V_{CC} signal is input, the spin state of the first magnetic region 26 may be an up state, and when a GDN signal is input, the spin state of the second magnetic region 28 may be a down state.

As shown in FIGS. 2(a) and 2(b), when a V_{CC} signal is input to the gate electrode 38, the third magnetic region 30 is polarized, and the spin state becomes a down state. As shown in FIGS. 2(a) and 2(b), when a GND signal is input to the gate electrode 38, the third magnetic region 30 is polarized, and the spin state becomes an up state. Accordingly, the spin transistor 1 can reduce the operation voltage which is the difference between the ground potential GND and the source voltage V_{CC}, compared with the difference in a conventional case. Thus, the power consumption can be lowered, and the DIBL (Drain-Induced Barrier Lowering) factor, the GIDL (Gate-Induced Drain Leakage), and the like can also be reduced.

It should be noted that the first through third magnetic regions 26, 28, and 30 may be made of the same ferromagnetic material having the band structure shown in FIG. 2(a), or at least only the third magnetic region 30 may be made of the ferromagnetic material. If the third magnetic region 30 is made of the ferromagnetic material, the first and second magnetic regions 26 and 28 are not limited to the ferromagnetic material having the band structure shown in FIG. 2(a), but are made of magnetic materials that have magnetization directions opposite from each other when a V_{CC} signal and a GND signal are input or even when a signal is not input, for example.

The first and second conductive regions 32 and 34 are made of a material that forms Schottky junctions with the first through third magnetic regions 26, 28, and 30. The first and second conductive regions 32 and 34 may be made of a Si single-crystal material, for example. Spin-polarized electrons travel through the first and second conductive regions 32 and 34, but there is no need to implant impurities in the first and second conductive regions 32 and 34. In addition, spin-polarized electrons travel beyond the tunnel barrier on the boundary between the first or second conductive region 32 or 34 and the third magnetic region 30. Therefore, there is no need to control the precession by the Rashba effect in the first and second conductive regions 32 and 34. Accordingly, the spin transistor 1 does not need to perform precise control on the sizes and the like with respect to the length of the channel region.

A method of manufacturing the spin transistor of this embodiment is described in the following description.

### (Method of Manufacturing the Spin Transistor)

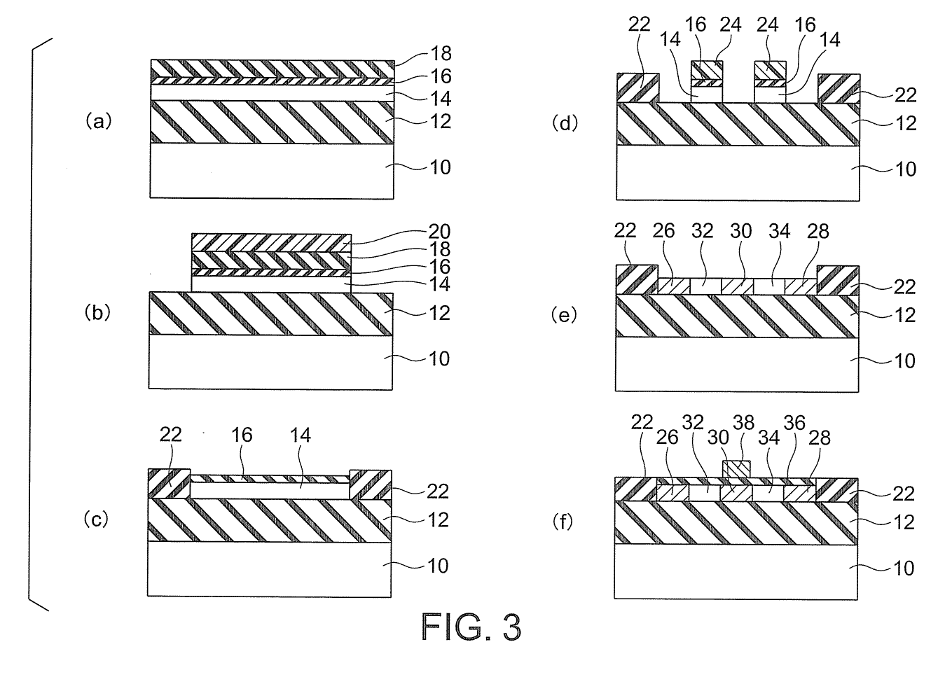

FIGS. 3(a) through 3(f) are cross-sectional views of related parts, showing the method of manufacturing the spin transistor according to the first embodiment.

First, a SOI substrate having the first insulating film 12 and a single-crystal film 14 formed thereon is prepared on the semiconductor substrate 10. The film thickness of the first insulating film 12 is 150 nm, for example. The single-crystal film 14 is a Si single-crystal film and has a film thickness of 20 nm, for example. A second insulating film 16 is then formed on the single-crystal film 14 by CVD (Chemical Vapor Deposition). The second insulating film 16 is a SiO₂ film, for example. The film thickness of the second insulating film 16 is 10 nm, for example. As shown in FIG. 3(a), a third insulating film 18 is formed on the second insulating film 16 by CVD. The third insulating film 18 is a SiN film, for example. The film thickness of the third insulating film 18 is 30 nm, for example.

A resist pattern 20 is then formed by a photolithography technique. As shown in FIG. 3(b), etching is performed on the third insulating film 18, the second insulating film 16, and the single-crystal film 14 by RIE (Reactive Ion Etching), with the resist pattern 20 serving as a mask. The resist pattern 20 is then removed.

As shown in FIG. 3(c), SiO₂ is then deposited on the first insulating film 12 and the third insulating film 18 by CVD, and polishing is performed by CMP (Chemical Mechanical Polishing), with the third insulating film 18 serving as a stopper. The third insulating film 18 is then removed, and the device isolating region 22 is formed.

As shown in FIG. 3(d), a resist pattern 24 is formed by a photolithography technique, and etching is performed on the second insulating film 16 and the single-crystal film 14 by RIE, with the resist pattern 24 serving as a mask. The resist pattern 24 is then removed.

As shown in FIG. 3(e), a half-metal ferromagnetic material is epitaxially grown by MBE (Molecular Beam Epitaxy) on the region through which the first insulating film 12 is exposed. Excess portions of the half-metal ferromagnetic material and the second insulating film 16 are then removed by CMP and wet etching. In this manner, the first through third magnetic regions 26, 28, and 30, and the first and second conductive regions 32 and 34 are formed.

The gate insulating film 36 is then formed by CVD. The gate insulating film 36 is a SiO₂ film, for example. The film thickness of the gate insulating film 36 is 3 nm, for example.

As shown in FIG. 3(f), a polycrystalline Si film having a film thickness of 100 nm is then formed by CVD. A SiN film is then formed as a hard mask on the polycrystalline Si film by CVD, and a resist pattern to be the mask for the gate electrode 38 is further formed by a photolithography technique. With the SiN film and the resist pattern serving as masks, patterning is then performed on the polycrystalline Si film by RIE, to form the gate electrode 38.

The interlayer insulating film 40 and the contacts 42, 44, 46, and 48 are then formed through known procedures, and the spin transistor 1 shown in FIGS. 1(a) and 1(b) is completed.

When the first through third ferromagnetic regions 26, 28, and 30 are made of different ferromagnetic materials, the following manufacturing procedures are added. Where the first through third magnetic regions 26, 28, and 30 are made of two ferromagnetic materials, the procedures up to the one illustrated in FIG. 3(d) are carried out, and a mask to expose the first insulating film 12 is then formed in a target region. A first ferromagnetic material is deposited to form a magnetic region. After the mask is removed, a mask to expose the first insulating film 12 is again formed in a target region. A second ferromagnetic material is then deposited to form a different magnetic region. Where the first through third magnetic regions 26, 28, and 30 are made of three different ferromagnetic materials, another procedure for forming a magnetic region is added to the above described procedures.

Next, an example and operations of an integrated circuit using spin transistors according to this embodiment are described.

### (Operations)

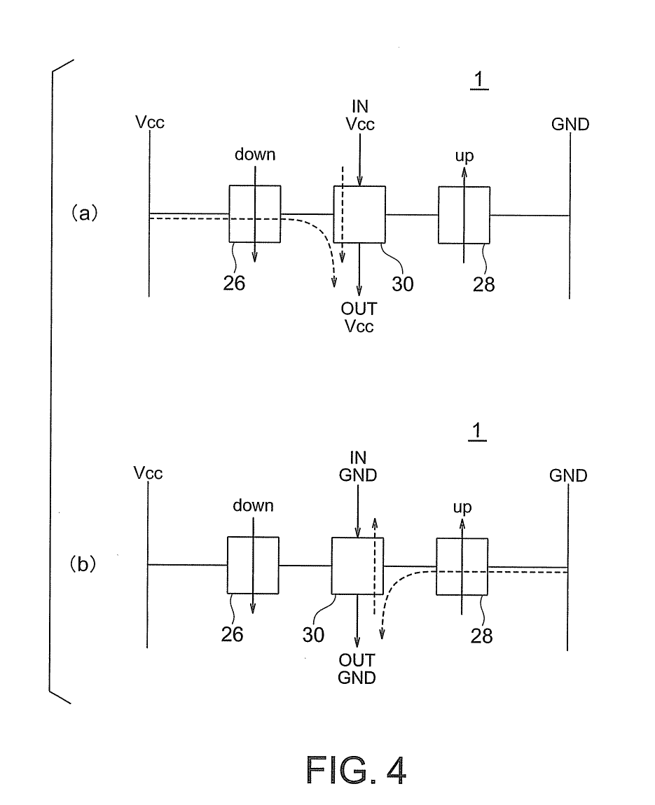

FIG. 4(a) is a circuit diagram showing a case where a V_{CC} signal is input to the third magnetic region according to the first embodiment. FIG. 4(b) is a circuit diagram showing a case where a GND signal is input to the third magnetic region according to the first embodiment. First, the case where a V_{CC} signal is input to the third magnetic region 30 is described.

When a V_{CC} signal output from the previous stage is input to the third magnetic region 30, the third magnetic region 30 has a downward magnetization direction, as shown in FIG. 4(a). The first magnetic region 26 also has a downward magnetization direction in accordance with a V_{CC} signal supplied from the power supply unit. Accordingly, a spin current spin-polarized in a downward direction can flow into the third magnetic region 30 via the first magnetic region 26 and the first conductive region 32.

Meanwhile, the second magnetic region 28 has an upward magnetization direction in accordance with an input GND signal. A spin current spin-polarized in an upward direction is about to flow into the third magnetic region 30 via the second conductive region 34 at this point, but cannot flow into the third magnetic region 30 since the third magnetic region 30 has downward spins.

Accordingly, the spin transistor 1 outputs the V_{CC} signal through the third magnetic region 30.

The case where a GND signal is input to the third magnetic region 30 is now described. When a GND signal output from the previous stage is input to the third magnetic region 30, the third magnetic region 30 has an upward magnetization direction, as shown in FIG. 4(b). Accordingly, a spin current spin-polarized in an upward direction can flow into the third magnetic region 30 via the second magnetic region 28 and the second conductive region 34.

Meanwhile, the first magnetic region 26 has a downward magnetization direction in accordance with a V_{CC} signal supplied from the power supply unit. A spin current spin-polarized in a downward direction is about to flow into the third magnetic region 30 via the first conductive region 32 at this point, but cannot flow into the third magnetic region 30 since the third magnetic region 30 has upward spins.

Accordingly, the spin transistor 1 outputs the GND signal through the third magnetic region 30.

### (Effects)

With the spin transistor according to the first embodiment, the problem of high standby power consumption due to fluctuations in the size of the channel region and others can be eliminated in a device using the spin information about carriers.

### Second Embodiment

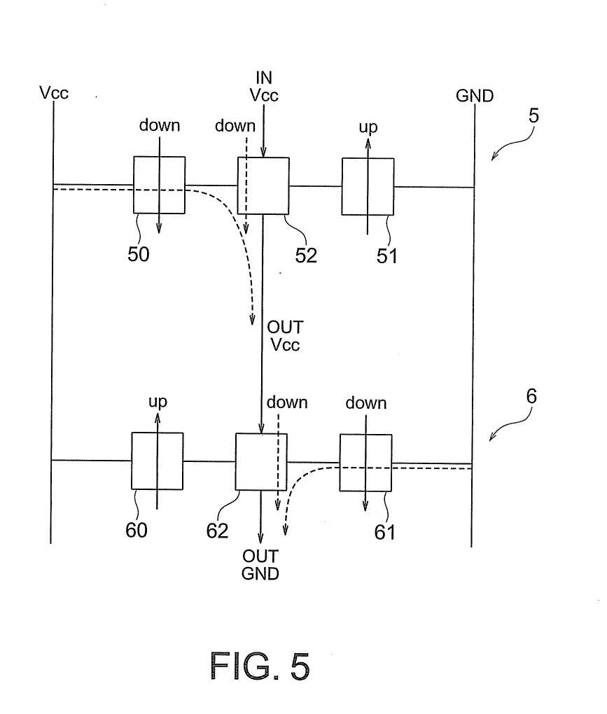

FIG. 5 is a circuit diagram of spin transistors that are cascade-connected according to a second embodiment. A circuit in which spin transistors of the first embodiment are cascade-connected is now described. In each of the embodiments described hereafter, the components having the same functions and structures as those of the first embodiment are denoted by the same reference numerals as those used in the first embodiment, and explanation of them will not be repeated.

### (Structure)

In the circuit shown in FIG. 5, a spin transistor 5 (the first spin transistor) and a spin transistor 6 (the second spin transistor) are cascade-connected. In the following description, the structures of the respective spin transistors are described. The structures of the spin transistors 5 and 6 are basically the same as the structure of the spin transistor 1, and therefore, the different aspects are now described. For ease of explanation, the conductive regions will be not explained in the following description.

As shown in FIG. 5, the spin transistor 5 is designed to include first through third magnetic regions 50, 51, and 52. The first magnetic region 50 is made of a ferromagnetic material that has a downward magnetization direction when a V_{CC} signal is input thereto. The second magnetic region 51 is made of a ferromagnetic material that has an upward magnetization direction when a GND signal is input thereto. The third magnetic region 52 is made of a ferromagnetic material that has a downward magnetization direction when a V_{CC} signal is input thereto, and has an upward magnetization direction when a GND signal is input thereto. As in the first embodiment, the first magnetic region 50 and the third magnetic region 52 are connected by a conductive region made of a semiconductor, for example, and the second magnetic region 51 and the third magnetic region 52 are connected by a conductive region made of a semiconductor, for example.

As shown in FIG. 5, the spin transistor 6 is designed to include first through third magnetic regions 60, 61, and 62. The first magnetic region 60 (the fourth magnetic region) is made of a ferromagnetic material that has an upward magnetization direction when a V_{CC} signal is input thereto. The second magnetic region 61 (the fifth magnetic region) is made of a ferromagnetic material that has a downward magnetization direction when a GND signal is input thereto. The third magnetic region 62 (the sixth magnetic region) is made of a ferromagnetic material that has a downward magnetization direction when a V_{CC} signal is input thereto, and has an upward magnetization direction when a GND signal is input thereto. As in the first embodiment, the first magnetic region 60 and the third magnetic region 62 are connected by a conductive region made of a semiconductor, for example, and the second magnetic region 61 and the third magnetic region 62 are connected by a conductive region made of a semiconductor, for example. The third magnetic region 52 and the third magnetic region 62 are also connected by a conductive region made of a semiconductor, for example. The first through third magnetic regions 50, 51, 52, 60, 61, and 62, and the conductive regions connecting those magnetic regions may be formed on a single insulating film, as in the first embodiment. In the following description, the operations of the circuit shown in FIG. 5 will be described.

### (Operations)

In a case where a V_{CC} signal output from the previous stage is input to the third magnetic region 52 of the spin transistor 5, the third magnetic region 52 has a downward magnetization direction. The first magnetic region 50 has a downward magnetization direction in accordance with a V_{CC} signal supplied from a power supply unit. Accordingly, a spin current spin-polarized in a downward direction can flow into the third magnetic region 52 via the first magnetic region 50.

Meanwhile, the second magnetic region 51 of the spin transistor 5 has an upward magnetization direction in accordance with an input GND signal. A spin current spin-polarized in an upward direction is about to flow into the third magnetic region 52 at this point, but cannot flow into the third magnetic region 52 since the third magnetic region 52 has downward spins.

Accordingly, the spin transistor 5 outputs the V_{CC} signal through the third magnetic region 52.

When the V_{CC} signal output from the spin transistor 5 is input to the third magnetic region 62 of the spin transistor 6, the third magnetic region 62 has a downward magnetization direction. The second magnetic region 61 has a downward magnetization direction in accordance with an input GND signal. Accordingly, a spin current spin-polarized in a downward direction can flow into the third magnetic region 62 via the second magnetic region 61.

Meanwhile, the first magnetic region 60 of the spin transistor 6 has an upward magnetization direction in accordance with a V_{CC} signal supplied from the power supply unit. A spin current spin-polarized in an upward direction is about to flow into the third magnetic region 62 at this point, but cannot flow into the third magnetic region 62 since the third magnetic region 62 has downward spins.

Accordingly, the spin transistor 6 outputs the GND signal through the third magnetic region 62.

### (Effects)

According to the second embodiment, a cascade connection in a device using spin transistors characterized by low power consumption can be realized.

### Third Embodiment

Next, a NAND operational circuit using a spin transistor is described as an example of a logic operational circuit. Since a number of NAND operational circuits are used for an integrated circuit, the area occupied by the NAND operational circuits can be made smaller by reducing the number of components forming each NAND operational circuit, and the area of the entire integrated circuit can be made smaller, accordingly.

### (Structure)

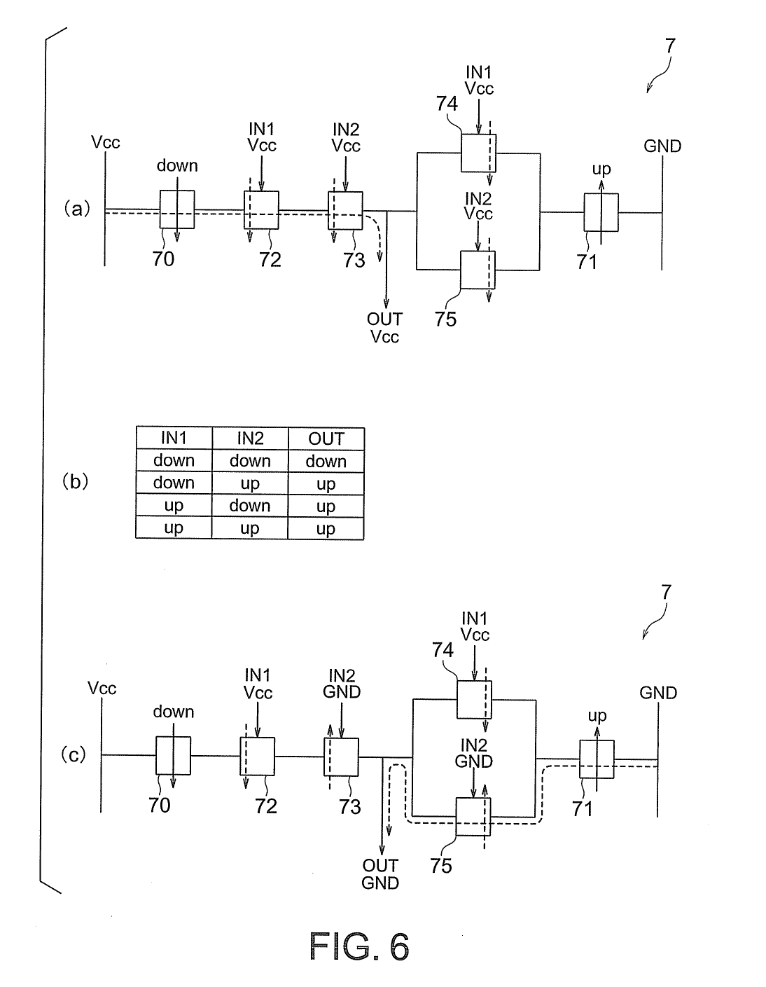

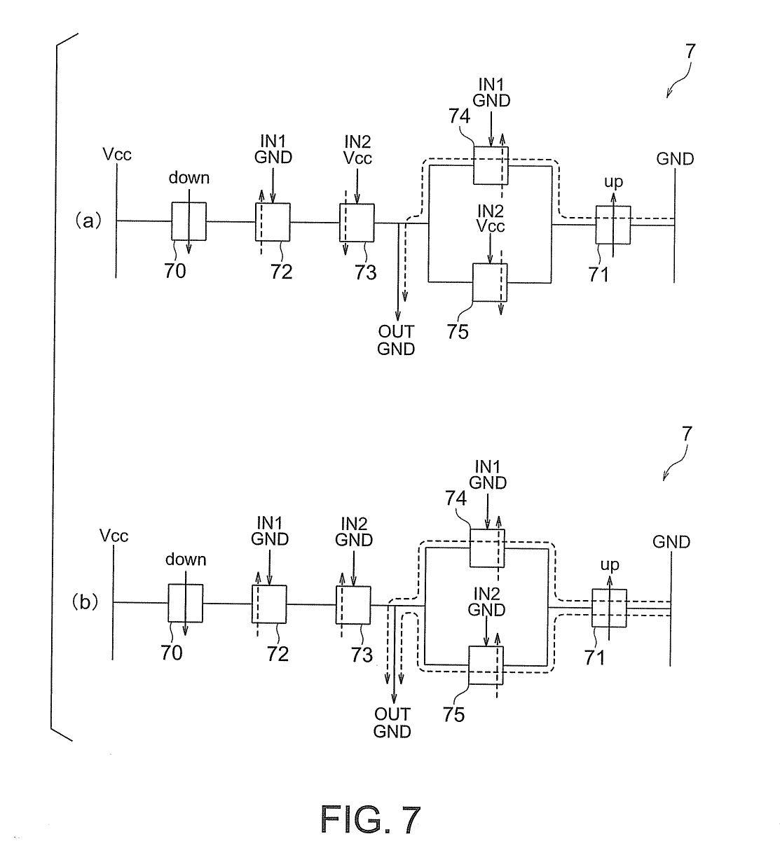

FIGS. 6(a), 6(c), 7(a), and 7(b) are circuit diagrams of the NAND operational circuit using a spin transistor according to a third embodiment. FIG. 6(b) is a truth table of the NAND operational circuit according to the third embodiment.

As shown in FIG. 6(a), the NAND operational circuit 7 is designed to include first through sixth magnetic regions 70, 71, 72, 73, 74, and 75. In the NAND operational circuit 7, conductive regions are formed between the respective first through sixth magnetic regions 70, 71, 72, 73, 74, and 75, as in the first embodiment. The first through sixth magnetic regions 70, 71, 72, 73, 74, and 75, and the conductive regions connecting those magnetic regions may be formed on a single insulating layer. The first magnetic region 70 is connected to the side of the source voltage V_{CC}, and is made of a ferromagnetic material that has a downward magnetization direction when a V_{CC} signal is input thereto. The second magnetic region 71 is connected to the side of the ground potential GND, and is made of a ferromagnetic material that has an upward magnetization direction when a GND signal is input thereto.

The third and fourth magnetic regions 72 and 73 are placed between the first and second magnetic regions 70 and 71, so as to be connected in series to the first magnetic region 70. Gate electrodes are formed immediately above the respective third and fourth magnetic regions 72 and 73 via a gate insulating film. The third and fourth magnetic regions 72 and 73 are made of a ferromagnetic material that has a downward magnetization direction when a V_{CC} signal is input thereto, and has an upward magnetization direction when a GND signal is input thereto.

The fifth and sixth magnetic regions 74 and 75 are formed between the second magnetic region 71 and the fourth magnetic region 73, so as to be connected in parallel. Gate electrodes are formed immediately above the respective fifth and sixth magnetic regions 74 and 75 via a gate insulating film. The fifth and sixth magnetic regions 74 and 75 are made of a ferromagnetic material that has a downward magnetization direction when a V_{CC} signal is input thereto, and has an upward magnetization direction when a GND signal is input thereto. That is, in the NAND operational circuit 7, third magnetic regions 30 of the first embodiment are combined to form the third through sixth magnetic regions 72 through 75. In the following description, the operations of the NAND operational circuit 7 are described.

### (Operations)

First, as shown in FIG. 6(a), a case where a V_{CC} signal is input to IN1 and a V_{CC} signal is also input to IN2 is described. It should be noted that IN1 represents the inputs of the third and fifth magnetic regions 72 and 74, and IN2 represents the inputs of the fourth and sixth magnetic regions 73 and 75.

Where a V_{CC} signal output from the previous stage is input to IN1 and IN2, the third through sixth magnetic regions 72 through 75 each have a downward magnetization direction. The first magnetic region 70 also has a downward magnetization direction in accordance with a V_{CC} signal supplied from a power supply unit. Accordingly, a spin current spin-polarized in a downward direction can flow into the third and fourth magnetic regions 72 and 73 via the first magnetic region 70.

Meanwhile, the second magnetic region 71 has an upward magnetization direction in accordance with an input GND signal. A spin current spin-polarized in an upward direction is about to flow into the fifth and sixth magnetic regions 74 and 75 at this point, but cannot flow into the fifth and sixth magnetic regions 74 and 75 since the fifth and sixth magnetic regions 74 and 75 have downward spins.

Accordingly, the NAND operational circuit 7 outputs the V_{CC} signal as OUT. Therefore, the NAND operational circuit 7 performs inputting and outputting with the combination “(IN1, IN2, OUT)=(down, down, down)” in the truth table shown in FIG. 6(b).

Next, a case where a V_{CC} signal is input to IN1 and a GND signal is input to IN2 as shown in FIG. 6(c) is described.

When a V_{CC} signal output from the previous stage is input to IN1, the third and fifth magnetic regions 72 and 74 each have a downward magnetization direction. When a GND signal output from the previous stage is input to IN2, the fourth and sixth magnetic regions 73 and 75 each have an upward magnetization direction.

The second magnetic region 71 has an upward magnetization direction in accordance with a GND signal. Accordingly, a spin current spin-polarized in an upward direction does not flow into the fifth magnetic region 74 having downward spins, but can flow into the sixth magnetic region 75 via the second magnetic region 71.

Meanwhile, the first magnetic region 70 has a downward magnetization direction in accordance with a V_{CC} signal supplied from the power supply unit. A spin current spin-polarized in a downward direction flows into the third magnetic region 72, and is about to further flow into the fourth magnetic region 73 at this point. However, the spin current cannot flow into the fourth magnetic region 73, since the fourth magnetic region 73 has upward spins.

Accordingly, the NAND operational circuit 7 outputs the GND signal as OUT. In this manner, the NAND operational circuit 7 performs inputting and outputting with the combination “(IN1, IN2, OUT)=(down, up, up)” in the truth table shown in FIG. 6(b).

Next, a case where a GND signal is input to IN1 and a V_{CC} signal is input to IN2 as shown in FIG. 7(a) is described.

When a GND signal output from the previous stage is input to IN1, the third and fifth magnetic regions 72 and 74 each have an upward magnetization direction. When a V_{CC} signal output from the previous stage is input to IN2, the fourth and sixth magnetic regions 73 and 75 each have a downward magnetization direction.

The second magnetic region 71 has an upward magnetization direction in accordance with a GND signal. Accordingly, a spin current spin-polarized in an upward direction does not flow into the sixth magnetic region 75 having downward spins, but can flow into the fifth magnetic region 74 via the second magnetic region 71.

Meanwhile, the first magnetic region 70 has a downward magnetization direction in accordance with a V_{CC} signal supplied from the power supply unit. A spin current spin-polarized in a downward direction cannot flow into the third magnetic region 72, since the third magnetic region 72 has upward spins.

Accordingly, the NAND operational circuit 7 outputs the GND signal as OUT. In this manner, the NAND operational circuit 7 performs inputting and outputting with the combination “(IN1, IN2, OUT)=(up, down, up)” in the truth table shown in FIG. 6(b).

Next, a case where a GND signal is input to IN1 and IN2 as shown in FIG. 7(b) is described.

When a GND signal output from the previous stage is input to IN1, the third and fifth magnetic regions 72 and 74 each have an upward magnetization direction. When a GND signal output from the previous stage is input to IN2, the fourth and sixth magnetic regions 73 and 75 each have an upward magnetization direction.

The second magnetic region 71 has an upward magnetization direction in accordance with a GND signal. Accordingly, a spin current spin-polarized in an upward direction can flow into the fifth and sixth magnetic regions 74 and 75 via the second magnetic region 71.

Meanwhile, the first magnetic region 70 has a downward magnetization direction in accordance with a V_{CC} signal supplied from the power supply unit. A spin current spin-polarized in a downward direction cannot flow into the third magnetic region 72, since the third magnetic region 72 has upward spins.

Accordingly, the NAND operational circuit 7 outputs the GND signal as OUT. Therefore, the NAND operational circuit 7 performs inputting and outputting with the combination “(IN1, IN2, OUT)=(up, up, up)” in the truth table shown in FIG. 6(b).

### (Effects)

According to the third embodiment, a logic operational circuit that can lower the standby power consumption can be formed.

### Effects of the Embodiments

According to each of the above described embodiments, an inversion layer is not formed immediately below the gate electrode 38, and spin-polarized electrons supplied from the first or second magnetic region 26 or 28 are output. Accordingly, the power consumption can be lowered.

In addition, according to each of the above described embodiments, a circuit is formed with the use of spin transistors. Accordingly, the number of components forming the circuit can be made smaller than that in a case where a circuit is formed with the use of conventional transistors. Thus, an increase in occupied area can be restrained.

It should be noted that the above described embodiments are merely examples, and do not limit the present invention. Various omissions, replacements, modifications, combinations, expansions, and corrections are possible in the above described embodiments, without departing from or changing the technical spirit of the invention.

The spin transistor 1 of the first embodiment includes the gate electrode 38 that controls the Fermi level of the third magnetic region 30. However, a contact may be formed directly on the third magnetic region 30, and a signal may be input through the contact. Likewise, in the third embodiment, contacts may be made on the third through sixth magnetic regions 72 through 75, and signals may be input through those contacts.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A spin transistor comprising:
a first magnetic region comprising a first input terminal and supplying a first polarized signal polarized in a first magnetization direction in accordance with a first input signal input through the first input terminal;
a second magnetic region comprising a second input terminal and supplying a second polarized signal polarized in a second magnetization direction opposite from the first magnetization direction in accordance with a second input signal input through the second input terminal, the second input signal being different from the first input signal;
a third input terminal; and
a third magnetic region comprising a first output terminal, and the third magnetic region outputting the first polarized signal supplied from the first magnetic region in accordance with a third input signal input through the third input terminal, and outputting the second polarized signal supplied from the second magnetic region in accordance with a fourth input signal input through the third input terminal, the fourth input signal being different from the third input signal.

2. The spin transistor according to claim 1, further comprising:
a first conductive region connecting the first magnetic region and the third magnetic region; and
a second conductive region connecting the second magnetic region and the third magnetic region.

3. The spin transistor according to claim 1, wherein the first through third magnetic regions and the first and second conductive regions are formed on a single insulating film.

4. The spin transistor according to claim 1, wherein the first through third magnetic regions are made of a half-metal ferromagnetic material.

5. An integrated circuit comprising:
a first spin transistor including:
a first magnetic region comprising a first input terminal and supplying a polarized signal polarized in a first magnetization direction in accordance with a first input signal input through the first input terminal;
a second magnetic region comprising a second input terminal and supplying a second polarized signal polarized in a second magnetization direction opposite from the first magnetization direction in accordance with a second input signal input through the second input terminal, the second input signal being different from the first input signal;
a third input terminal; and
a third magnetic region outputting the first polarized signal supplied from the first magnetic region in accordance with a third input signal input through the third input terminal, and outputting the second polarized signal supplied from the second magnetic region in accordance with a fourth input signal input through the third input terminal, the fourth input signal being different from the third input signal; and
a second spin transistor including:
a fourth magnetic region comprising a fourth input terminal and supplying a third polarized signal polarized in the second magnetization direction in accordance with the first input signal input through the fourth input terminal;
a fifth magnetic region comprising a fifth input terminal and supplying a fourth polarized signal polarized in the first magnetization direction in accordance with the second input signal input through the fifth input terminal; and
a sixth magnetic region outputting the fourth polarized signal supplied from the fifth magnetic region in accordance with the first polarized signal output from the third magnetic region of the first spin transistor, and outputting the third polarized signal supplied from the fourth magnetic region in accordance with the signal output from the third magnetic region of the first spin transistor in accordance with the second polarized signal output from the third magnetic region of the first spin transistor.

6. The integrated circuit according to claim 5, further comprising:
a first conductive region connecting the first magnetic region and the third magnetic region;
a second conductive region connecting the second magnetic region and the third magnetic region;
a third conductive region connecting the fourth magnetic region and the sixth magnetic region;
a fourth conductive region connecting the fifth magnetic region and the sixth magnetic region; and
a fifth conductive region connecting the third magnetic region and the sixth magnetic region.

7. The integrated circuit according to claim 5, wherein the first through sixth magnetic regions and the first through fifth conductive regions are formed on a single insulating film.

8. The integrated circuit according to claim 5, wherein the first through sixth magnetic regions are made of a half-metal ferromagnetic material.

9. An integrated circuit comprising:
a first magnetic region comprising a first input terminal and supplying a first polarized signal polarized in a first magnetization direction in accordance with a first input signal input through the first input terminal;
a second magnetic region comprising a second input terminal and supplying a second polarized signal polarized in a second magnetization direction opposite from the first magnetization direction in accordance with a second input signal input through the second input terminal, the second input signal being different from the first input signal;
an output terminal;
two third magnetic regions each comprising a third input terminal, and each of the third magnetic regions outputting a third polarized signal polarized in the first magnetization direction in accordance with a third input signal input through the third input terminal, and outputting a fourth polarized signal polarized in the second magnetization direction in accordance with a fourth input signal input through the third input terminal, the fourth input signal being different from the third input signal; and
two fourth magnetic regions each comprising a fourth input terminal, and each of the fourth magnetic regions outputting a fifth polarized signal polarized in the first magnetization direction in accordance with a fifth input signal input through the fourth input terminal, and outputting a sixth polarized signal polarized in the second magnetization direction in accordance with a sixth input signal input through the fourth input terminal, the sixth input signal being different from the fifth input signal,
one of the two third magnetic regions receiving the first polarized signal supplied from the first magnetic region,
one of the two fourth magnetic regions receiving the second polarized signal supplied from the second magnetic region,
the signal output from at least one of the other one of the two third magnetic regions and the other one of the two fourth magnetic regions being sent to the output terminal.

10. The integrated circuit according to claim 9, wherein
the other one of the two third magnetic regions receives the second polarized signal supplied from the second magnetic region,
the other one of the two fourth magnetic regions receives the polarized signal supplied from the one of the third magnetic regions, and
the polarized signal output from the other one of the two third magnetic regions and the polarized signals output from the two fourth magnetic regions are sent to the output terminal.

11. The integrated circuit according to claim 10, further comprising:
a first conductive region connecting the first magnetic region and the one of the two third magnetic regions;
a second conductive region connecting the second magnetic region and the other one of the two third magnetic regions, and connecting the second magnetic region and the one of the two fourth magnetic regions;
a third conductive region connecting the one of the two third magnetic regions and the other one of the two fourth magnetic regions; and
a fourth conductive region connecting the two fourth magnetic regions and the two third magnetic regions to the output terminal.

12. The integrated circuit according to claim 9, wherein the first through fourth magnetic regions and the first through fourth conductive regions are formed on a single insulating film.

13. The integrated circuit according to claim 9, wherein the first through fourth magnetic regions are made of a half-metal ferromagnetic material.

14. The spin transistor according to claim 2, wherein the first through third magnetic regions and the first and second conductive regions are formed on a single insulating film.

15. The spin transistor according to claim 2, wherein the first through third magnetic regions are made of a half-metal ferromagnetic material.

16. The spin transistor according to claim 3, wherein the first through third magnetic regions are made of a half-metal ferromagnetic material.
